(19) United States
(12) Patent Application Publication
(10) Pub. No.: US 2012/0181545 A1
(43) Pub. Date: Jul. 19, 2012

(54) SEMICONDUCTOR DEVICE AND METHOD FOR PRODUCING SAME, AND DISPLAY DEVICE PROVIDED WITH SEMICONDUCTOR DEVICE

(75) Inventor: Hiroshi Matsukizono, Osaka-shi (JP)

(73) Assignee: SHARP KABUSHIKI KAISHA, Osaka-shi (JP)

(21) Appl. No.: 13/498,749

(22) PCT Filed: Sep. 17, 2010
(86) PCT No.: PCT/JP2010/066205

§ 371 Date: Mar. 28, 2012

(30) Foreign Application Priority Data
Sep. 30, 2009 (JP) 2009-226728

(51) Int. Cl. H01L 29/786; H01L 21/20

(52) U.S. Cl. 257/72; 257/66; 438/479; 257/E29.273; 257/E21.09

(57) ABSTRACT

A thin film diode (10A) included in a semiconductor device according to the present invention includes: a semiconductor layer having first, second, and third semiconductor regions; an insulating layer (22A, 23A) formed on the semiconductor layer; and first and second contact holes penetrating through the insulating layer (22A, 23A). The first semiconductor region contains an impurity of a first-conductivity type at a first concentration; the second semiconductor region contains an impurity of a second-conductivity type different from the first conductivity type at a second concentration; and the third semiconductor region contains the first-conductivity type impurity at a third concentration lower than the first concentration, or contains the second-conductivity type impurity at a third concentration lower than the second concentration. The first semiconductor region conforms to the first contact hole, or the second semiconductor region conforms to the second contact hole.

### REFERENCE TO RELATED APPLICATIONS

This application is the national stage under 35 USC 371 of International Application No. PCT/JP2010/066205, filed Sep. 17, 2010, which claims priority from Japanese Patent Application No. 2009-226728, filed Sep. 30, 2009, the entire contents of which are incorporated herein by reference.

### FIELD OF THE INVENTION

The present invention relates to a semiconductor device, a production method thereof, and a display device having a semiconductor device.

### BACKGROUND OF THE INVENTION

Currently, liquid crystal display devices having a TFT (Thin Film Transistor) in each pixel (TFT-type liquid crystal display devices) are broadly used in television sets and the like. Among medium- to small-sized liquid crystal display device that are used in laptop computers, mobile phones, and the like, there are actual products in which part of the driving circuitry is integrated into a substrate having TFTs formed thereon (referred to as a “TFT substrate”).

Furthermore, in recent years, display devices have been proposed in which image sensors utilizing thin film diodes (TFDs) are integrally formed on a TFT substrate (e.g., Patent Documents 1 and 2). As described in Patent Document 1, a display device having optical touch sensors can be composed by providing a TFD for each pixel.

### CITATION LIST

### Patent Literature

[Patent Document 1] Japanese Laid-Open Patent Publication No. 2006-3857
[Patent Document 2] Japanese Laid-Open Patent Publication No. 2009-16855

### SUMMARY OF INVENTION

As display devices increase in resolution, it becomes necessary for the TFD to be provided in each pixel to become smaller. However, small TFDs make it difficult to obtain a sufficient photocurrent.

Patent Document 1 states that, in a TFD having a p⁺ region/a p⁻ region (or n⁻ region)/an n⁺ region, a sufficient photocurrent is obtained by making the length of the p⁻ region (or n⁻ region) along a direction horizontal to the substrate longer than the p⁺ region and the n⁺ region. In the present specification, the p⁺ region and the n⁺ region may collectively be referred to as “high concentration regions”. Moreover, the p⁻ region (or n⁻ region) may be referred to as a low concentration region (or an intrinsic region; i region).

However, in the TFD production method described in Patent Document 1, the high concentration regions (the p⁺ region and the n⁺ region) are formed through a generic photolithography process, and therefore need to have a structure that takes into consideration an alignment margin for ensuring overlap with the corresponding electrodes. In other words, the smallest size of the high concentration regions is determined by the alignment margin, which imposes a limit on the downsizing of the TFD.

The photocurrent of a TFD has characteristics such that the photocurrent increases as the length of the low concentration region increases. Therefore, the photocurrent decreases as the length of the low concentration region decreases. Moreover, if the length of the low concentration region fluctuates, the size of the photocurrent will fluctuate. These problems become more outstanding as the TFD becomes smaller.

The present invention has been made in view of the above problems, and a main objective thereof is to provide: a semiconductor device having a TFD which provides a sufficient photocurrent even when downsized; a production method thereof; and a display device having such a semiconductor device.

A semiconductor device according to the present invention is a semiconductor device comprising an insulative substrate and a plurality of thin film diodes carried on the insulative substrate, wherein, each of the plurality of thin film diodes includes a semiconductor layer being formed on the insulative substrate and having first, second, and third semiconductor regions, an insulating layer formed on the semiconductor layer, first and second contact holes penetrating through the insulating layer, a first electrode being formed on the insulating layer and connected to the first semiconductor region within the first contact hole, and a second electrode being formed on the insulating layer and connected to the second semiconductor region within the second contact hole, the first semiconductor region containing an impurity of a first-conductivity type at a first concentration, the second semiconductor region containing an impurity of a second-conductivity type different from the first conductivity type at a second concentration, the third semiconductor region containing the first-conductivity type impurity at a third concentration lower than the first concentration or containing the second-conductivity type impurity at a third concentration lower than the second concentration; and the first semiconductor region conforms to the first contact hole, or the second semiconductor region conforms to the second contact hole.

In one embodiment, as viewed from a normal direction of the insulative substrate, an outer edge of the first semiconductor region is substantially defined by the first contact hole, or an outer edge of the second semiconductor region is substantially defined by the second contact hole.

In one embodiment, the first semiconductor region conforms to the first contact hole, and the second semiconductor region conforms to the second contact hole.

In one embodiment, the plurality of thin film diodes are arranged in a matrix array of rows and columns, and thin film diodes arranged along the row direction are joined with one another in one of the first and second semiconductor regions.

The semiconductor device according to one embodiment further comprises a plurality of thin film transistors carried on the insulative substrate.

A display device according to the present invention comprises any of the aforementioned semiconductor devices.

A production method of a semiconductor device according to the present invention is a production method of a semiconductor device having an insulative substrate and a plurality of thin film diodes carried on the insulative substrate, the production method comprising: step a of providing an insulative substrate; step b of forming a semiconductor layer on the insulative substrate; step c of forming an insulating layer on the semiconductor layer; step d of forming first and second contact holes penetrating through the insulating layer; step e of forming first, second, and third semiconductor regions by implanting first and second-conductivity type impurities to the semiconductor layer, the first semiconductor region containing an impurity of a first-conductivity type at a first concentration, the second semiconductor region containing an impurity of a second-conductivity type different from the first conductivity type at a second concentration, the third semiconductor region containing the first-conductivity type impurity at a third concentration lower than the first concentration or containing the second-conductivity type impurity at a third concentration lower than the second concentration; and step f of forming on the insulating layer a first electrode connected to the first semiconductor region within the first contact hole and a second electrode connected to the second semiconductor region within the second contact hole, wherein step f includes a step of forming the first semiconductor region in a self-aligning manner with respect to the first contact hole, or a step of forming the second semiconductor region in a self-aligning manner with respect to the second contact hole.

In one embodiment, step f includes a step of forming the first semiconductor region in a self-aligning manner with respect to the first contact hole and a step of forming the second semiconductor region in a self-aligning manner with respect to the second contact hole.

According to the present invention, there is provided a semiconductor device having a TFD which provides a sufficient photocurrent even when downsized, a production method thereof, and a display device having such a semiconductor device.

### BRIEF DESCRIPTION OF DRAWINGS

FIG. 1 (a) is a schematic cross-sectional view showing the structure of a thin film diode 10A included in a semiconductor device 100A according to an embodiment of the present invention; and (b) is a schematic plan view of the semiconductor device 100A according to an embodiment of the present invention.

FIG. 2 (a) is a schematic plan view showing the construction of a display device having the semiconductor device 100A; and (b) is a circuit diagram showing a portion of a display region 13 in (a).

FIG. 3 (a) to (e) are schematic cross-sectional views for describing a production method of a thin film diode 10A.

FIG. 4 (a) to (d) are schematic cross-sectional views for describing a production method of a thin film diode 10A.

FIG. 5 (a) is a schematic cross-sectional view showing the structure of a thin film diode 10B included in a semiconductor device 100B according to another embodiment; and (b) is a schematic plan view of the semiconductor device 100B according to an embodiment of the present invention.

FIG. 6 (a) is a schematic plan view of a semiconductor device 100C according to still another embodiment; and (b) is a schematic plan view of a semiconductor device 100D according to still another embodiment.

FIG. 7 (a) to (e) are schematic cross-sectional views for describing a production method of a thin film diode 10B.

FIG. 8 (a) to (d) are schematic cross-sectional views for describing a production method of a thin film diode 10B.

### DETAILED DESCRIPTION OF THE INVENTION

Hereinafter, with reference to the drawings, a semiconductor device according to an embodiment of the present invention and a production method thereof will be described. In the following, a TFT substrate having a thin film diode for each pixel, which is for use in a liquid crystal display device, will be illustrated as the semiconductor device; however, the present invention is not limited thereto.

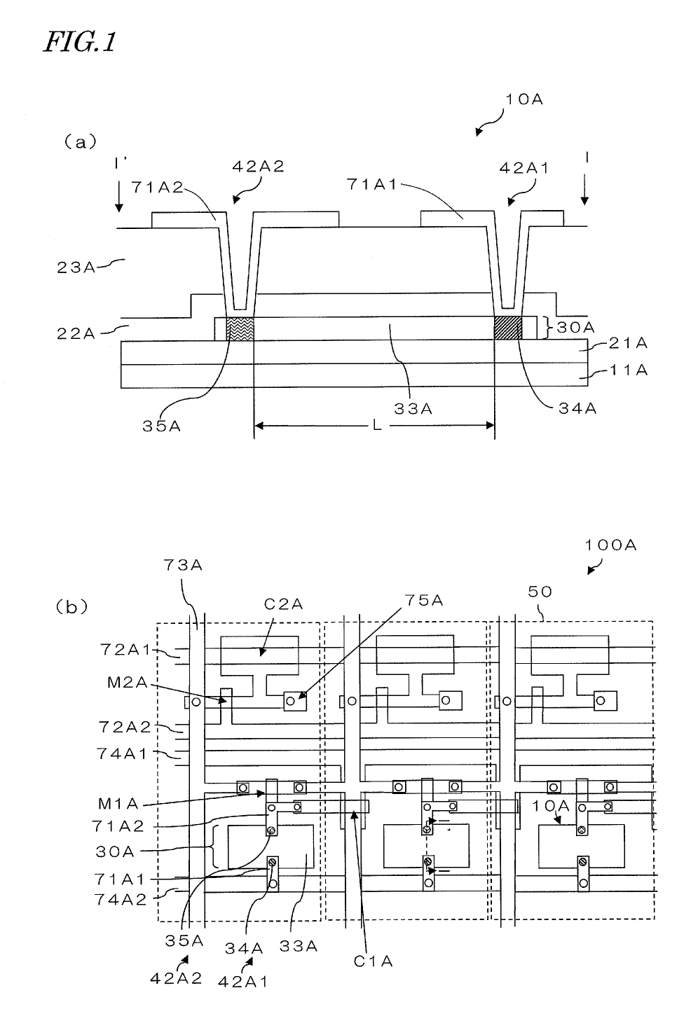

With reference to FIG. 1 to FIG. 3, the structure of a semiconductor device 100A according to an embodiment of the present invention and a production method thereof will be described.

FIGS. 1(a) and (b) show the structure of the semiconductor device 100A. FIG. 1(a) is a schematic cross-sectional view showing the structure of a thin film diode 10A included in the semiconductor device 100A; and FIG. 1(b) is a schematic plan view of the semiconductor device 100A.

The semiconductor device 100A is a TFT substrate for use in a liquid crystal display device, having a thin film diode 10A shown in FIG. 1(a) in each pixel. As shown in FIG. 1(b), the semiconductor device 100A includes an insulative substrate not shown (e.g., a glass substrate) 11A and thin film diodes 10A and thin film transistors M2A carried on the insulative substrate 11A. On the insulative substrate 11A, Cs lines 72A1, gate bus lines 72A2, read signal lines (RWS) 74A1, and reset signal lines (RST) 74A2 extending along the row direction and source bus lines 73A extending along the column direction are formed in a lattice, such that each group of meshes corresponds to a pixel 50. The pixels 50 are arranged in a matrix array, such that a thin film diode 10A, a follower thin film transistor M1A, and a storage capacitor C1A are disposed for each pixel 50. Moreover, a thin film transistor M2A, a pixel capacitor C2A, and a pixel electrode 75A are also disposed for each pixel 50, the thin film transistor M2A being connected to a gate bus line 72A2 and a source bus line 73A.

As shown in FIG. 1(a), each thin film diode 10A includes a semiconductor layer 30A formed on the insulative substrate 11A, and insulating layers 22A and 23A formed on the semiconductor layer 30A. The semiconductor layer 30A includes a first semiconductor region 34A, a second semiconductor region 35A, and a third semiconductor region 33A.

Furthermore, the thin film diode 10A includes: a first contact hole 42A1 and a second contact hole 42A2 penetrating through the insulating layers 22A and 23A; a first electrode 71A1 being formed on the insulating layer 23A and connected to the first semiconductor region 34A within the first contact hole 42A1; and a second electrode 71A2 being formed on the insulating layer 23A and connected to the second semiconductor region 35A within the second contact hole 42A2.

The first semiconductor region 34A contains an impurity of a first-conductivity type (e.g., a p type impurity) at a first concentration; the second semiconductor region 35A contains an impurity of a second-conductivity type (e.g., an n type impurity), which is different from the first conductivity type, at a second concentration; and the third semiconductor region 33A contains the first-conductivity type impurity at a third concentration lower than the first concentration, or contains the second-conductivity type impurity at a third concentration lower than the second concentration. That is, the first semiconductor region 34A is a p⁺ region; the second semiconductor region 35A is an n⁺ region; and the third semiconductor region 33A is a p⁻ region or an n⁻ region (i region).

In the thin film diode 10A, the first semiconductor region 34A conforms to the first contact hole 42A1, and the second semiconductor region 35A conforms to the second contact hole 42A2. In other words, the two high concentration regions respectively conform to the corresponding contact holes. Herein, that a high concentration region “conforms to a contact hole” means that, through the production process of the thin film diode 10A, the high concentration region has been formed in a self-aligning manner with respect to the contact hole. Therefore, the two-dimensional expanse of the high concentration region as viewed from the substrate normal direction is substantially defined by the contact hole.

Furthermore, since the length L of the third semiconductor region 33A is greater than those of the first semiconductor region 34A and the second semiconductor region 35A, a depletion layer which is formed between the first semiconductor region 34A and the second semiconductor region 35A has a broad expanse in the third semiconductor region 33A, thus providing an advantage in that the photocurrent is increased and the efficiency of light/current conversion is improved.

Moreover, by forming the first semiconductor region 34A and the second semiconductor region 35A so as to respectively conform to the corresponding contact holes (42A1, 42A2), there is provided an advantage in that the misalignment between each semiconductor region and the corresponding electrode (first electrode 71A1, second electrode 71A2) is reduced.

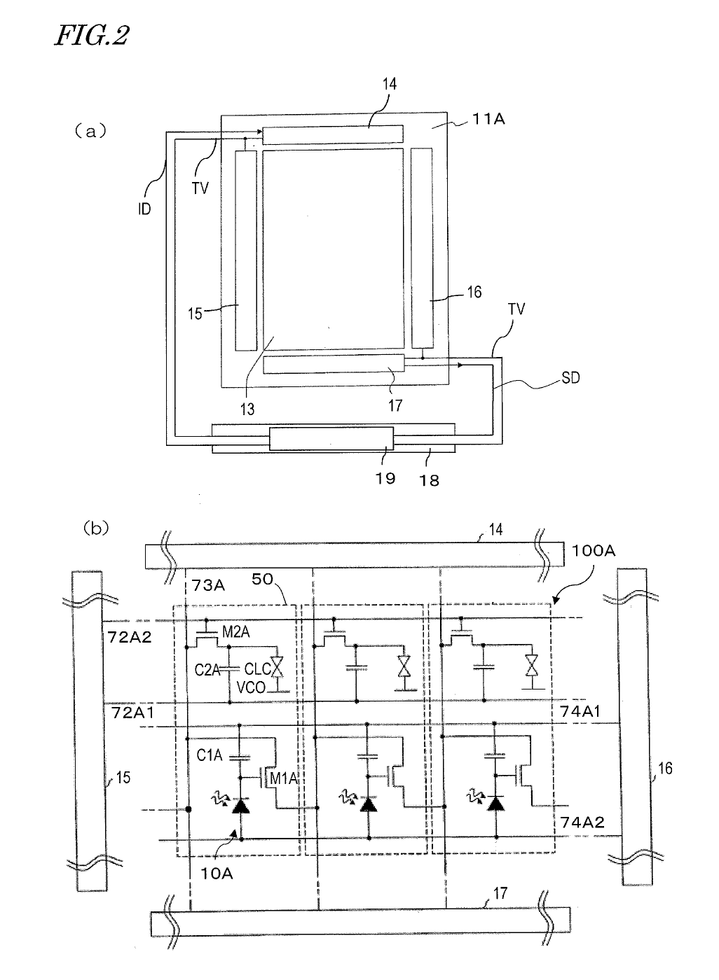

Next, FIG. 2(a) is a schematic plan view showing the construction of a display device having the semiconductor device 100A. The display device of FIG. 2(a) has an image capturing function (image sensors), and includes the insulative substrate 11A and a semiconductor substrate 18. On the insulative substrate 11A are a display region 13 having the gate bus lines 72A2 and source bus lines 73A, and a peripheral region, in which a source driver 14 for driving the source bus lines 73A, a gate driver 15 for driving the gate bus lines 72A2, a sensor read driver 17 for capturing and outputting an image, and a sensor scan driver 16 for driving the image sensors are provided. A logic IC 19 for performing display control and image capturing control is provided on the semiconductor substrate 18. The logic IC 19 may be mounted on the insulative substrate 11A, or externally connected to the insulative substrate 11A via an FPC, for example. Note that a display device having a semiconductor device 100B, 100C, or 100D described later will also have a similar construction. Note that, in FIG. 2(a), TV denotes a timing control signal and power voltage; SD denotes a sensor data signal; and ID denotes an image data signal.

FIG. 2(b) is a circuit diagram showing a portion of the display region 13. The display region 13 in FIG. 2(b) includes a thin film transistor M2A formed near each intersection between a source bus line and a gate bus line, a liquid crystal capacitor CLC and a pixel capacitor C2A connected between one end of the thin film transistor M2A and a Cs line 72A1, as well as the thin film diodes 10A, the follower thin film transistors M1A, and the storage capacitors C1A. Note that a display device having the below-described semiconductor device 100B, 100C, or 100D will also be represented by a similar circuit diagram.

The operation principles of the image sensors will be briefly described.

First, a reset signal at a high level is supplied to a reset signal line (RST) 74A2. As a result, a forward bias is applied to a thin film diode 10A. At this time, since the potential of the gate electrode of the follower thin film transistor M1A is lower than a threshold voltage of the follower thin film transistor M1A, the follower thin film transistor M1A is in a non-conducting state.

Next, the potential of the reset signal line (RST) 74A2 is set to a low level. As a result, an integration period of photocurrent begins. In this integration period, a photocurrent which is in proportion to the amount of light entering the thin film diode 10A flows out from the storage capacitor C1A, so that the storage capacitor C1A becomes discharged. In this integration period, too, the potential of the gate electrode of the follower thin film transistor M1A is lower than the threshold voltage of the follower thin film transistor M1A, so that the follower thin film transistor M1A remains in a non-conducting state.

Next, a read signal at a high level is supplied to the read signal line (RWS) 74A1. As a result, the integration period is ended, and a read period begins. As the read signal is supplied, charge is injected and stored in the storage capacitor C1A, and the potential of the gate electrode of the follower thin film transistor M1A becomes higher than the threshold voltage of the follower thin film transistor M1A. As a result, the follower thin film transistor M1A enters a conducting state, whereby an output voltage (VPIX) is read from the follower thin film transistor M1A via the source bus line 73A. VPIX is in proportion to an integral of the photocurrent in the thin film diode 10A during the integration period.

Next, the potential of the read signal line (RWS) 74A1 is lowered to a low level, thus ending the read period. Although the operation principles of an image sensor in the semiconductor device 100A have been described, the operation principles of an image sensor in the below-described semiconductor devices 100B, 100C, and 100D are also similar.

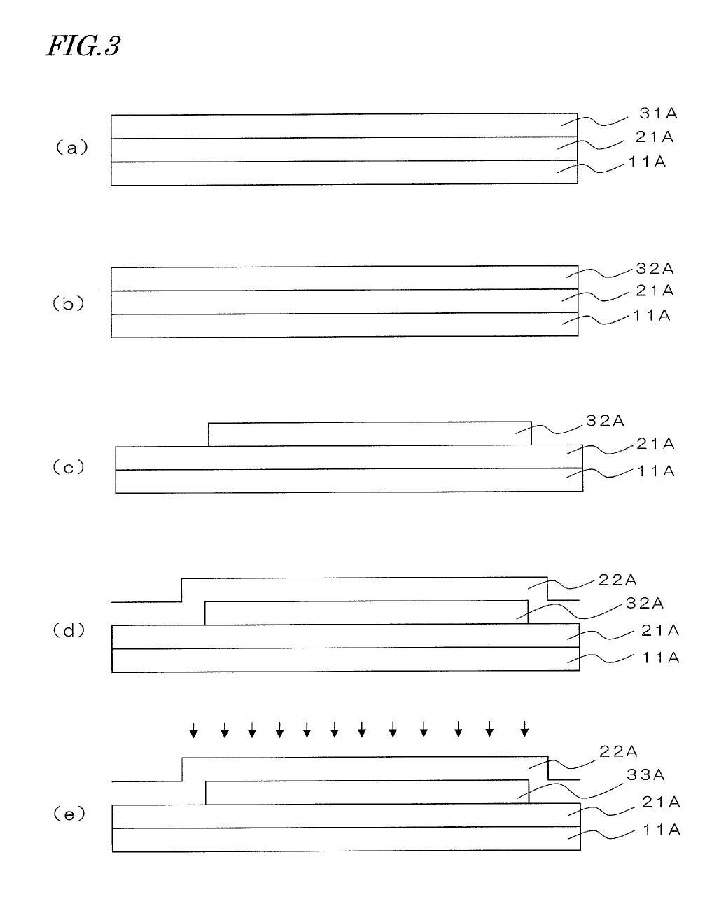

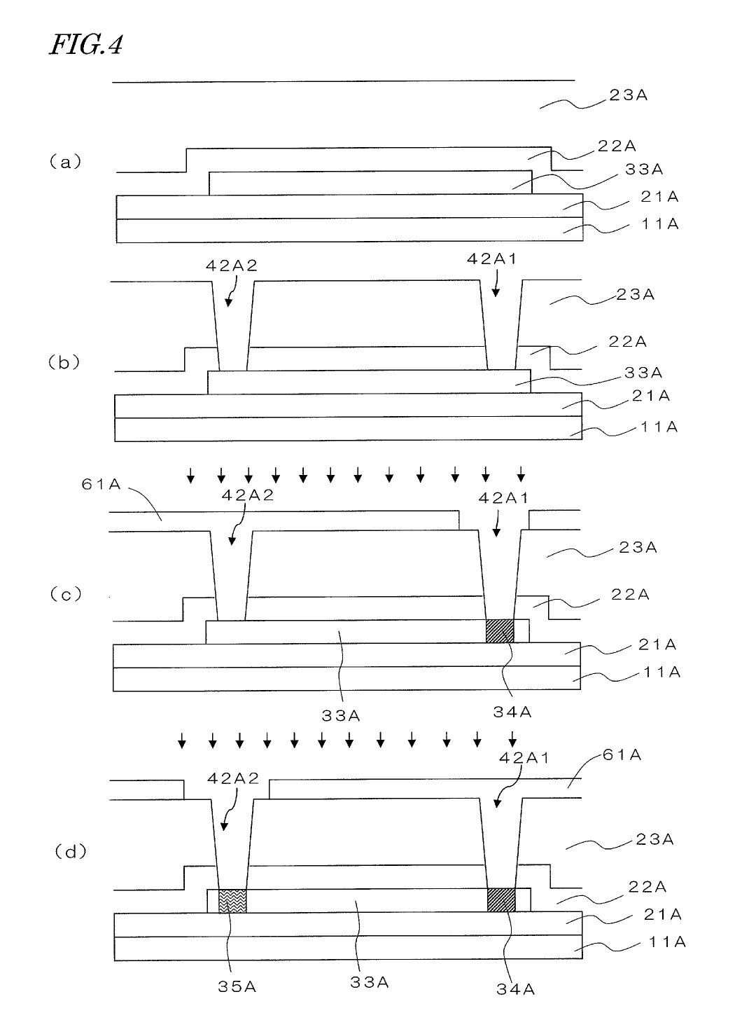

Next, with reference to FIG. 3 and FIG. 4, a production method of the semiconductor device 100A will be described. Hereinafter, a production method of a thin film diode 10A of the semiconductor device 100A will be mainly described.

First, as shown in FIG. 3(a), a basecoat layer 21A containing e.g. SiNₓ (silicon nitride) or SiOₓ (silicon oxide) is formed on a glass substrate 11A by a CVD (Chemical Vapor Deposition) technique. Next, by a CVD technique, sputtering technique, or the like, an amorphous silicon (a-Si) layer 31A is formed on the basecoat layer 21A.

Next, as shown in FIG. 3(b), the amorphous silicon layer 31A is subjected to a thermal annealing treatment to dehydrate the amorphous silicon layer 31A, and thereafter it is subjected to excimer laser irradiation, thus crystallizing the amorphous silicon layer 31A to form a polycrystalline silicon layer 32A.

Next, as shown in FIG. 3(c), the polycrystalline silicon layer 32A is patterned into an island shape by a known method.

Next, as shown in FIG. 3(d), a first insulating layer 22A containing SiOₓ or the like is formed on the island shape of polycrystalline silicon layer 32A by a CVD technique or the like.

Next, as shown in FIG. 3(e), by using a photoresist not shown as a mask, a low concentration of boron ions is implanted to the polycrystalline silicon layer 32A, thereby forming a p⁻ region 33A. The entire polycrystalline silicon layer into which boron has been implanted may also be referred to as a polycrystalline silicon layer 33A.

Next, as shown in FIG. 4(a), on the first insulating layer 22A, a second insulating layer 23A is formed by stacking SiNₓ, SiOₓ, and the like by a known method, for example. In this case, the structure of the second insulating layer 23A is not limited to a multilayer structure.

Next, as shown in FIG. 4(b), through a photolithography process or the like, contact holes 42A1 and 42A2 reaching the polycrystalline silicon layer 33A are formed in the first insulating layer 22A and the second insulating layer 23A.

Next, as shown in FIG. 4(c), the portion to become a p⁺ region described below is masked with a resist 61A or the like, and phosphorus ions are implanted to a portion of the p⁻ region 33A, thereby forming an n⁺ region 34A.

Next, as shown in FIG. 4(d), the n⁺ region 34A is masked with a resist 61A or the like, and a high concentration of boron ions is implanted to a portion of the p⁻ region 33A, thereby forming a p⁺ region 35A. Then, a thermal annealing treatment is conducted. By heating the insulative substrate 11A, the dopants in the n⁺ region 34A and the p⁺ region 35A are activated, and at the same time, the polycrystalline silicon layer 33A is hydrogenated through diffusion of hydrogen that is contained in the second insulating layer 23A.

Thereafter, the resist 61A is removed, and by using e.g. ITO (Indium Thin Oxide), IZO (Indium Zinc Oxide), or the like, an electrode 71A1 which connects to the n⁺ region 34A within the contact hole 42A1 and an electrode 71A2 which connects to the p⁺ region 35A within the contact hole 42A2 are formed on the second insulating layer 23A by a sputtering technique, for example. As a result of this, the thin film diode 10A shown in FIG. 1(a) is obtained. A transparent electrode material is desirable for the electrodes 71A1 and 71A2 in order not to hinder light from entering the junction portion here; however, without being limited to transparent, an opaque metal material may also be used.

As described above, in the production method of the present embodiment, the n⁺ region 34A and the p⁺ region 35A are formed in a self-aligning manner with respect to the contact holes 42A1 and 42A2. In other words, the n⁺ region 34A and the p⁺ region 35A are formed as a result of impurities (e.g., phosphorus ions or boron ions) being implanted to the semiconductor layer exposed through the above-described contact holes, such that a desired semiconductor region (high concentration region) is formed in each impurity-implanted region. Although the impurities diffuse during the heat treatment (activation annealing) after the impurity implantation, it can be said that the final extent of the high concentration regions is substantially defined by the contact holes.

Thus, since the high concentration regions are formed in a self-aligning manner with respect to the contact holes, the length of the p⁻ region 33A in the finally-obtained thin film diode 10A will not vary, thus providing an advantage of reducing characteristics variations between one thin film diode and another. Since stray light is restrained from entering the thin film diode and thus the optical S/N (Signal/Noise) ratio is increased, it is particularly effective when designing the p⁻ region 33A so as to have a large length. Furthermore, since it is possible to make the n⁺ region 34A and the p⁺ region 35A smaller and make the length of the p⁻ region 33A correspondingly larger, a greater photocurrent can be obtained; therefore, the higher resolution the display device has, the more advantage there is.

Furthermore, since the doping is conducted in a separate step from the doping of the high concentration regions of the thin film transistors not shown, which are concurrently formed with the thin film diodes, it is possible to set an arbitrary dose. This permits a dose which is high enough to minimize the contact resistance with the electrode described below, thus resulting in an advantage in that a large photocurrent can be obtained.

Moreover, since the doping for forming the high concentration regions can be effected not by way of the first insulating layer 22A and the second insulating layer 23A, there is an advantage in that the process can be performed with a low acceleration voltage. As a result, damage on the semiconductor layer due to doping can be reduced and good P-I and I-N interfaces are obtained, whereby PIN diodes having excellent characteristics can be obtained.

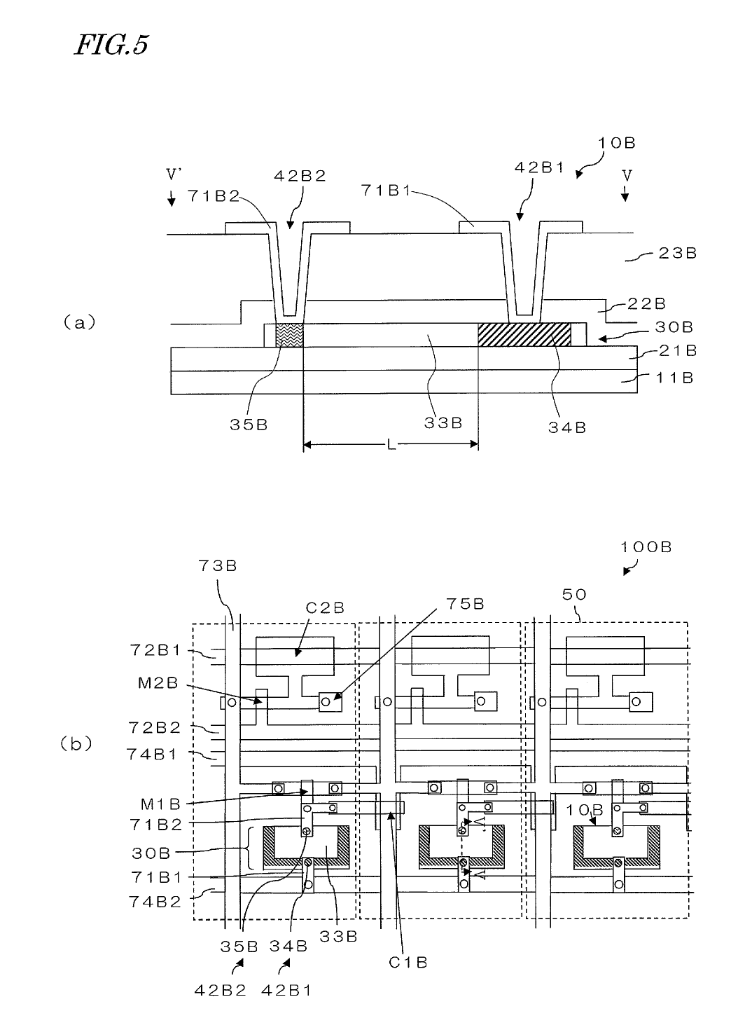

Next, with reference to FIG. 5 to FIG. 8, the structures and production methods of semiconductor devices 100B, 100C, and 100D according to other embodiments of the present invention will be described.

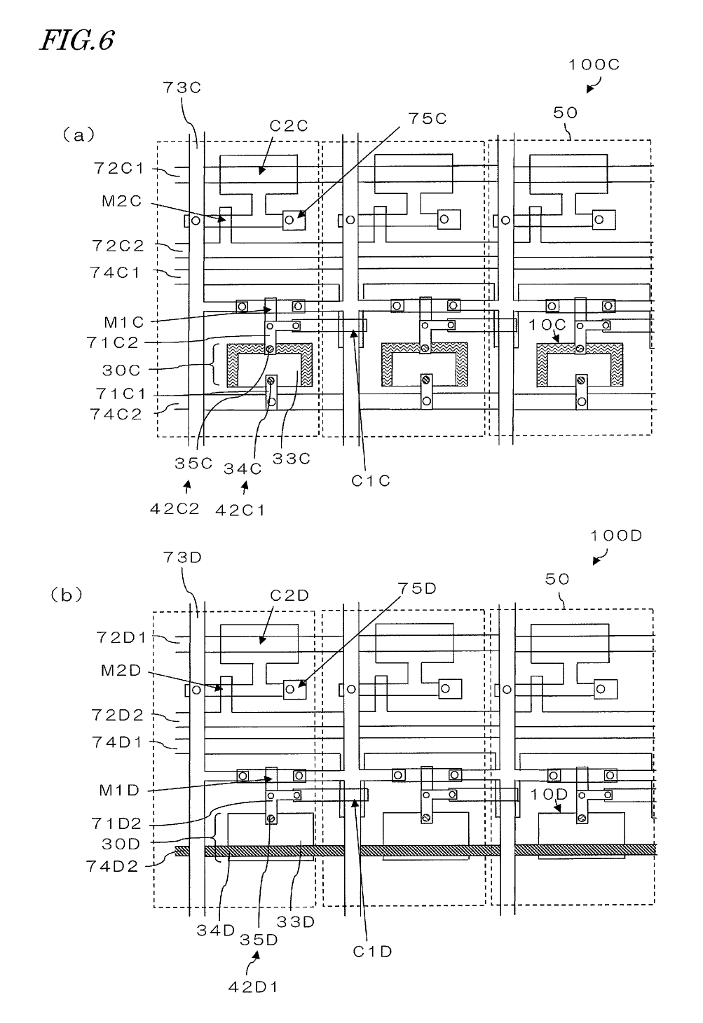

FIGS. 5(a) and (b) show the structure of a semiconductor device 100B according to another embodiment of the present invention. FIG. 5(a) is a schematic cross-sectional view showing the structure of a thin film diode 10B included in the semiconductor device 100B, and FIG. 5(b) is a schematic plan view of the semiconductor device 100B. FIG. 6(a) is a schematic plan view of a semiconductor device 100C, and FIG. 6(b) is a schematic plan view of the semiconductor device 100D.

The semiconductor device 100B is a TFT substrate for use in a liquid crystal display device, having a thin film diode 10B shown in FIG. 5(a) in each pixel. As shown in FIG. 5(b), the semiconductor device 100B includes an insulative substrate not shown (e.g., a glass substrate) 11B and thin film diodes 10B and thin film transistors M2B carried on the insulative substrate 11B. On the insulative substrate 11B, Cs lines 72B1, gate bus lines 72B2, read signal lines (RWS) 74B1, and reset signal lines (RST) 7482 extending along the row direction and source bus lines 73B extending along the column direction are formed in a lattice, such that each group of meshes corresponds to a pixel 50. The pixels 50 are arranged in a matrix array, such that a thin film diode 10B, a follower thin film transistor M1B, and a storage capacitor C1B are disposed for each pixel 50. Moreover, a thin film transistor M2B, a pixel capacitor C2B, and a pixel electrode 75B are also disposed for each pixel, being connected to a gate bus line 72B2 and a source bus line 73B.

As shown in FIG. 5(a), each thin film diode 10B includes a semiconductor layer 30B formed on the insulative substrate 11B, and insulating layers 22B and 23B formed on the semiconductor layer 30B. The semiconductor layer 30B includes a first semiconductor region 348, a second semiconductor region 35B, and a third semiconductor region 338.

Furthermore, the thin film diode 10B includes: a first contact hole 42B1 and a second contact hole 42B2 penetrating through the insulating layers 22B and 23B; a first electrode 71B1 being formed on the insulating layer 23B and connected to the first semiconductor region 34B within the first contact hole 42B1; and a second electrode 71B2 being formed on the insulating layer 23B and connected to the second semiconductor region 35B within the second contact hole 42B2.

The first semiconductor region 348 contains an impurity of a first-conductivity type (e.g., a p type impurity) at a first concentration; the second semiconductor region 35B contains an impurity of a second-conductivity type (e.g., an n type impurity), which is different from the first conductivity type, at a second concentration; and the third semiconductor region 33B contains the first-conductivity type impurity at a third concentration lower than the first concentration, or contains the second-conductivity type impurity at a third concentration lower than the second concentration. That is, the first semiconductor region 34B is a p⁺ region; the second semiconductor region 35B is an n⁺ region; and the third semiconductor region 33B is a p⁻ region or an n⁻ region (i region).

In the thin film diode 10B, the second semiconductor region 35B conforms to the second contact hole 42B2. In other words, one high concentration region conforms to its corresponding contact hole. Herein, that a high concentration region “conforms to a contact hole” means that, in the production process of the thin film diode 10B, the high concentration region has been formed in a self-aligning manner with respect to the contact hole. Therefore, the two-dimensional expanse of the high concentration region as viewed from the substrate normal direction is substantially defined by the contact hole.

Moreover, by forming the second semiconductor region 35B so as to conform to its corresponding contact hole 42B2, there is provided an advantage in that the misalignment between the second semiconductor region 35B and its corresponding electrode (second electrode 71B2) is reduced.

Moreover, other than the thin film diodes 10B, constructions such as thin film diodes 10C and thin film diodes 10D shown in FIG. 6(a) and FIG. 6(b) may also be used.

As shown in FIG. 6(a), the semiconductor device 100C includes an insulative substrate not shown and thin film diodes 10C and thin film transistors M2C carried on the insulative substrate. On the insulative substrate, Cs lines 72C1, gate bus lines 72C2, read signal lines (RWS) 74C1, and reset signal lines (RST) 74C2 extending along the row direction and source bus lines 73C extending along the column direction are formed in a lattice, such that each group of meshes corresponds to a pixel 50. The pixels 50 are arranged in a matrix array, such that a thin film diode 10C, a follower thin film transistor M1C, and a storage capacitor C1C are disposed for each pixel 50. Moreover, a thin film transistor M2C, a pixel capacitor C2C, and a pixel electrode 75C are also disposed for each pixel 50, being connected to the gate bus line 72C2 and the source bus line 73C.

Each thin film diode 10C includes a semiconductor layer 30C having a first semiconductor region 34C, a second semiconductor region 35C, and a third semiconductor region 33C, and an insulating layer formed on the semiconductor layer 30C.

Furthermore, the thin film diode 10C includes: a first contact hole 42C1 and a second contact hole 42C2 penetrating through the insulating layer; a first electrode 71C1 being formed on the insulating layer and connected to the first semiconductor region 34C within the first contact hole 42C1; and a second electrode 71C2 being formed on the insulating layer 23C and connected to the second semiconductor region 35C within the second contact hole 42C2.

The first semiconductor region 34C contains an impurity of a first-conductivity type (e.g., a p type impurity) at a first concentration; the second semiconductor region 35C contains an impurity of a second-conductivity type (e.g., an n type impurity), which is different from the first conductivity type, at a second concentration; and the third semiconductor region 33C contains the first-conductivity type impurity at a third concentration lower than the first concentration, or contains the second-conductivity type impurity at a third concentration lower than the second concentration. That is, the first semiconductor region 34C is a p⁺ region; the second semiconductor region 35C is an n⁺ region, and the third semiconductor region 33C is a p⁻ region or an n⁻ region (i region).

In the thin film diode 10C, the first semiconductor region 34C conforms to the first contact hole 42C1. In other words, one high concentration region conforms to its corresponding contact hole. Herein, that a high concentration region “conforms to a contact hole” means that, in the production process of the thin film diode 10C, the high concentration region has been formed in a self-aligning manner with respect to the contact hole. Therefore, the two-dimensional expanse of the high concentration region as viewed from the substrate normal direction is substantially defined by the contact hole. Moreover, by forming the first semiconductor region 34C so as to conform to its corresponding contact hole 42C1, there is provided an advantage in that the misalignment between the first semiconductor region 34C and its corresponding electrode (first electrode 71C1) is reduced.

As shown in FIG. 6(b), the semiconductor device 100D includes an insulative substrate not shown and thin film diodes 10D and thin film transistors M2D carried on the insulative substrate. On the insulative substrate, Cs lines 72D1, gate bus lines 72D2, read signal lines (RWS) 74D1, and reset signal lines (RST) 74D2 extending along the row direction and source bus lines 73D extending along the column direction are formed in a lattice, such that each group of meshes corresponds to a pixel 50. The pixels 50 are arranged in a matrix array, such that a thin film diode 10D, a follower thin film transistor M1D, and a storage capacitor C1D are disposed for each pixel 50. Moreover, a thin film transistor M2D, a pixel capacitor C2D, and a pixel electrode 75D are also disposed for each pixel 50, being connected to the gate bus line 72D2 and the source bus line 73D.

Each thin film diode 10D includes a semiconductor layer 30D having a first semiconductor region 34D, a second semiconductor region 35D, and a third semiconductor region 33D, and an insulating layer formed on the semiconductor layer 30D.

Furthermore, the thin film diode 10D includes: a first contact hole 42D1 penetrating through the insulating layer; and a first electrode 71D2 being formed on the insulating layer and connected to the second semiconductor region 35D within the first contact hole 42D1. Moreover, a plurality of thin film diodes 10D arranged along the row direction are joined with one another via their first semiconductor regions 34D.

The first semiconductor region 34D contains an impurity of a first-conductivity type (e.g., a p type impurity) at a first concentration; the second semiconductor region 35D contains an impurity of a second-conductivity type (e.g., an n type impurity), which is different from the first conductivity type, at a second concentration; and the third semiconductor region 33D contains the first-conductivity type impurity at a third concentration lower than the first concentration, or contains the second-conductivity type impurity at a third concentration lower than the second concentration. That is, the first semiconductor region 34D is a p⁺ region; the second semiconductor region 35D is an n⁺ region; and the third semiconductor region 33D is a p⁻ region or an n⁻ region (i region).

In the thin film diode 10D, the second semiconductor region 35D conforms to the first contact hole 42D1. In other words, one high concentration region conforms to its corresponding contact hole. Herein, that a high concentration region “conforms to a contact hole” means that, in the production process of the thin film diode 10D, the high concentration region has been formed in a self-aligning manner with respect to the contact hole. Therefore, the two-dimensional expanse of the high concentration region as viewed from the substrate normal direction is substantially defined by the contact hole. Moreover, by forming the second semiconductor region 35D so as to conform to its corresponding contact hole 42D1, there is provided an advantage in that the misalignment between the second semiconductor region and its corresponding electrode (first electrode 71D2) is reduced.

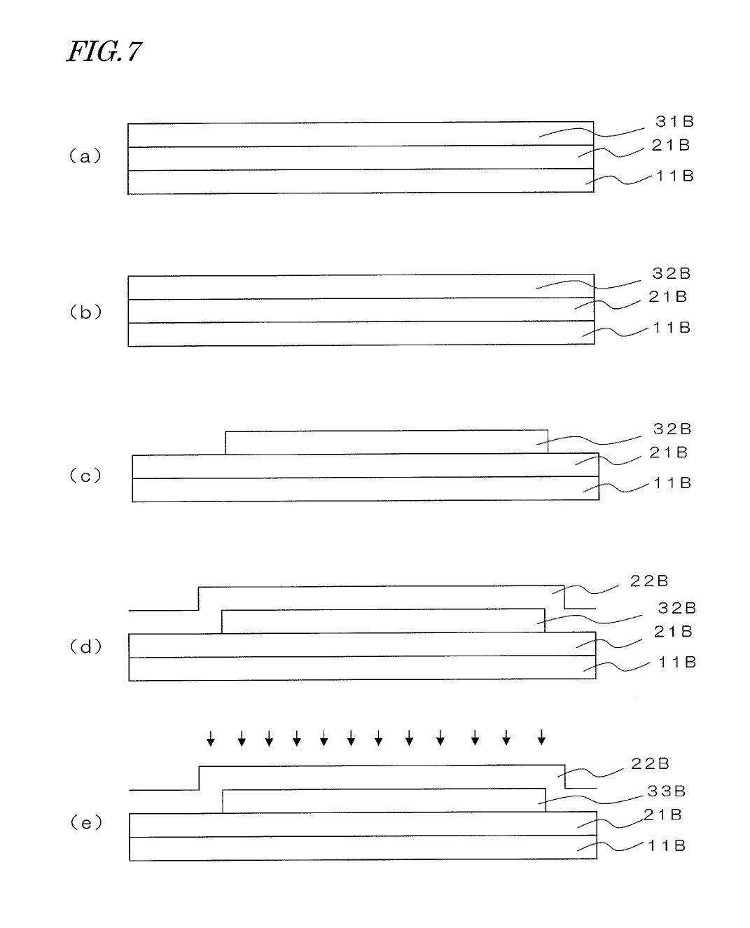

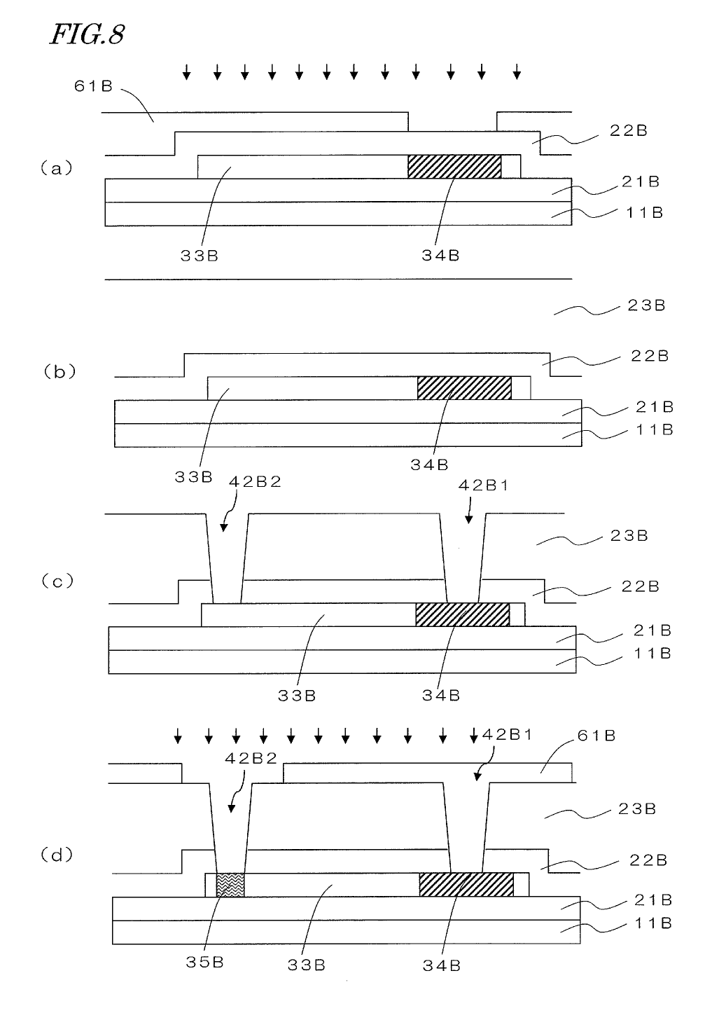

Next, with reference to FIG. 7 and FIG. 8, a production method of the semiconductor device 100B will be described. Hereinafter, a production method of a thin film diode 10B of the semiconductor device 100B will be mainly described.

First, as shown in FIG. 7(a), a basecoat layer 21B containing e.g. SiNₓ or SiOₓ is formed on a glass substrate 11B by a CVD technique or the like. Next, by a CVD technique, a sputtering technique, or the like, an amorphous silicon layer 31B is formed on the basecoat layer 21B.

Next, as shown in FIG. 7(b), the amorphous silicon layer 31B is subjected to a thermal annealing to dehydrate the amorphous silicon layer 31B, and thereafter it is subjected to excimer laser irradiation, thus crystallizing the amorphous silicon layer 31B to form a polycrystalline silicon layer 32B.

Next, as shown in FIG. 7(c), the polycrystalline silicon layer 32B is patterned into an island shape by a known method.

Next, as shown in FIG. 7(d), a first insulating layer 22B in which SiOₓ or the like is used is formed on the island shape of polycrystalline silicon layer 32B by a CVD technique or the like.

Next, as shown in FIG. 7(e), by using a resist not shown or the like as a mask, a low concentration of boron ions is implanted to the polycrystalline silicon layer 32B, thereby forming a p⁻ region 33B. The entire polycrystalline silicon layer into which boron has been implanted may also be referred to as a polycrystalline silicon layer 33B.

Next, as shown in FIG. 8(a), by using a mask of photoresist 61B or the like, a high concentration phosphorus ions is implanted to a portion of the p⁻ region 33B, thereby forming an n⁺ region 34B.

Next, as shown in FIG. 8(b), on the first insulating layer 22B, a second insulating layer 23B is formed by stacking SiNₓ, SiOₓ, and the like by a known method, for example. In this case, the structure of the second insulating layer 23B is not limited to a multilayer structure.

Next, as shown in FIG. 8(c), through a photolithography process or the like, contact holes 42B1 and 42B2 for the semiconductor layer, reaching the polycrystalline silicon layer 33B, are formed in the first insulating layer 22B and the second insulating layer 23B.

Next, as shown in FIG. 8(d), the n⁺ region 34B is masked with a photoresist 61B or the like, and boron ions are implanted to a portion of the p⁻ region 33B, thereby forming a p⁺ region 35B. At this time, the p⁺ region 35B is formed in a self-aligning manner with respect to the aforementioned contact hole.

Next, a thermal annealing treatment is conducted. By heating the substrate, the dopants in the n⁺ region 34B and the p⁺ region 35B are activated, and at the same time, the polycrystalline silicon layer 33B is hydrogenated through diffusion of hydrogen that is contained in the second insulating layer 23B.

Thereafter, the resist 61B is removed, and by using e.g. ITO, IZO, or the like, an electrode 71B1 which connects to the n⁺ region 34B within the contact hole 42B1 and an electrode 7182 which connects to the p⁺ region 35B within the contact hole 42B2 are formed on the second insulating layer 23B by a sputtering technique, for example. As a result of this, the thin film diode 10B shown in FIG. 5(a) is obtained. A transparent electrode material is desirable for the electrodes 71B1 and 71B2 in order not to hinder light from entering the junction portion here; however, without being limited to transparent, an opaque metal material may also be used.

Although an example where only the p⁺ region 35B is formed in a self-aligning manner with respect to a contact hole is illustrated here, this is not a limitation. So long as one of the high concentration regions, i.e., the p⁺ region 35B and the n⁺ region 34B, is formed in a self-aligning manner with respect to a contact hole, the aforementioned semiconductor device 100C or 100D will be obtained, for example, and the effects of the present invention will be obtained for that high concentration region in a similar manner to the above-described semiconductor device 100A. Note that the other high concentration region may be formed by using a known process such as a photolithography process.

Although TFT-type liquid crystal display devices having a thin film diode for each pixel are illustrated as examples of the display device, the present invention is applicable to other display devices, such as organic EL display devices. Moreover, without being limited to display devices having a thin film diode for each pixel, it is applicable to display devices having an image sensor region separately from the display region, as is disclosed in Patent Document 2. It is certainly applicable to an image sensor itself, and to any electronic device, other than display devices, in which image sensors are integrated.

The present invention is applicable to a semiconductor device, a production method thereof, and a display device having a semiconductor device.

### REFERENCE SIGNS LIST

11A, 11B insulative substrate
22A, 22B, 22C, 22D first insulating layer
23A, 23B, 23C, 23D second insulating layer
30A, 30B, 30C, 30D semiconductor layer
33A, 33B, 33C, 33D p⁻ region
34A, 34B, 34C, 34D n⁺ region
35A, 35B, 35C, 35D p⁺ region
42A1, 42A2, 42B1, 42B2, 42C1, 42C2, 42D1 contact hole
50 pixel
61A, 61B resist
71A1, 71A2, 71B1, 71B2, 71C1, 71C2, 71D2 electrode
72A1, 72B1, 72C1, 72D1 Cs line
72A2, 72B2, 72C2, 72D2 gate bus line
73A, 73B, 73C, 73D source bus line
74A1, 74B1, 74C1, 74D1 read signal line (RWS)
74A2, 74B2, 74C2, 74D2 reset signal line (RST)
75A, 75B, 75C, 75D pixel electrode
M1A, M1B, M1C, M1D follower TFT
M2A, M2B, M2C, M2D thin film transistor (pixel TFT)
C1A, C1B, C1C, C1D storage capacitor
C2A, C2B, C2C, C2D pixel capacitor

1. A semiconductor device comprising an insulative substrate and a plurality of thin film diodes carried on the insulative substrate, wherein,
each of the plurality of thin film diodes includes
a semiconductor layer being formed on the insulative substrate and having first, second, and third semiconductor regions,
an insulating layer formed on the semiconductor layer,
first and second contact holes penetrating through the insulating layer,
a first electrode being formed on the insulating layer and connected to the first semiconductor region within the first contact hole, and
a second electrode being formed on the insulating layer and connected to the second semiconductor region within the second contact hole,
the first semiconductor region containing an impurity of a first-conductivity type at a first concentration, the second semiconductor region containing an impurity of a second-conductivity type different from the first conductivity type at a second concentration, the third semiconductor region containing the first-conductivity type impurity at a third concentration lower than the first concentration or containing the second-conductivity type impurity at a third concentration lower than the second concentration; and
the first semiconductor region conforms to the first contact hole, or the second semiconductor region conforms to the second contact hole.

2. The semiconductor device of claim 1, wherein, as viewed from a normal direction of the insulative substrate, an outer edge of the first semiconductor region is substantially defined by the first contact hole, or an outer edge of the second semiconductor region is substantially defined by the second contact hole.

3. The semiconductor device of claim 1, wherein the first semiconductor region conforms to the first contact hole, and the second semiconductor region conforms to the second contact hole.

4. The semiconductor device of claim 1, wherein the plurality of thin film diodes are arranged in a matrix array of rows and columns, and thin film diodes arranged along the row direction are joined with one another in one of the first and second semiconductor regions.

5. The semiconductor device of claim 1, further comprising a plurality of thin film transistors carried on the insulative substrate.

6. A display device comprising the semiconductor device of claim 5.

7. A production method of a semiconductor device having an insulative substrate and a plurality of thin film diodes carried on the insulative substrate, the production method comprising:
step a of providing an insulative substrate;
step b of forming a semiconductor layer on the insulative substrate;
step c of forming an insulating layer on the semiconductor layer;
step d of forming first and second contact holes penetrating through the insulating layer;
step e of forming first, second, and third semiconductor regions by implanting first and second-conductivity type impurities to the semiconductor layer, the first semiconductor region containing an impurity of a first-conductivity type at a first concentration, the second semiconductor region containing an impurity of a second-conductivity type different from the first conductivity type at a second concentration, the third semiconductor region containing the first-conductivity type impurity at a third concentration lower than the first concentration or containing the second-conductivity type impurity at a third concentration lower than the second concentration; and
step f of forming on the insulating layer a first electrode connected to the first semiconductor region within the first contact hole and a second electrode connected to the second semiconductor region within the second contact hole, wherein
step e includes a step of forming the first semiconductor region in a self-aligning manner with respect to the first contact hole, or a step of forming the second semiconductor region in a self-aligning manner with respect to the second contact hole.

8. The production method of a semiconductor device of claim 7, wherein step e includes a step of forming the first semiconductor region in a self-aligning manner with respect to the first contact hole and a step of forming the second semiconductor region in a self-aligning manner with respect to the second contact hole.
